(19) United States
(12) Patent Application Publication
(10) Pub. No.: US 2021/0214835 A1
(43) Pub. Date: Jul. 15, 2021

(54) MASK SHEET, MASK COMPONENT, AND VAPOR-DEPOSITION METHOD

(71) Applicants: Hefei Xinsheng Optoelectronics Technology Co., Ltd., Hefei (CN); BOE TECHNOLOGY GROUP CO., LTD., Beijing (CN)

(72) Inventors: Hai XU, Beijing (CN); Li SUN, Beijing (CN)

(21) Appl. No.: 16/760,184

(22) PCT Filed: Oct. 14, 2019
(86) PCT No.: PCT/CN2019/111061

§ 371 Date: Apr. 29, 2020

(30) Foreign Application Priority Data
Nov. 13, 2018 (CN) 201811347484.1

(51) Int. Cl. C23C 14/04; C23C 14/24; H01L 51/00

(52) U.S. Cl. CPC C23C 14/042; C23C 14/24; H01L 51/56; H01L 51/001; H01L 51/0011

(57) ABSTRACT

The present disclosure describes a mask sheet, a mask component, and a vapor-deposition method, the mask sheet being disposed on a mask frame. The mask sheet includes a magnetic material and has a first surface and a second surface. The first surface of the mask sheet faces away from the mask frame, the second surface of the mask sheet faces to the mask frame, and a plurality of convex structures protrude from the first surface of the mask sheet.

### CROSS REFERENCE TO RELATED APPLICATIONS

The present application is based upon International Application No. PCT/CN2019/111061, filed on Oct. 14, 2019, which claims the benefit of and priority to Chinese Patent Application No. 201811347484.1, filed on Nov. 13, 2018, the contents of which being incorporated by reference in their entireties herein.

### TECHNICAL FIELD

The present disclosure relates to the technical field of semiconductor vapor-deposition device and, in particular, to a mask sheet, a mask component, and a vapor-deposition method.

### BACKGROUND

In a printing process of an OLED device, a vapor-deposition machine is usually used as a device for implementing the printing process. The mask used by the existing vapor-deposition machine is a mask with an open center. The mask is mainly composed of a mask frame and a mask sheet tensioned thereon.

After a required glass (substrate) is transferred to the mask, it is aligned, and then a touch plate moves downward and presses the glass, so that the glass and the mask sheet above the mask are closely attached. Then, vapor-deposition of various materials is performed and, meanwhile, a cooling water pipe is also provided in the touch plate, which can play a role of cooling the glass.

It should be noted that the information disclosed in the above Background section is only for enhancing the understanding of the background of the present disclosure, and therefore may include information that does not constitute prior art known to those of ordinary skill in the art.

### SUMMARY

An object of the present disclosure is to provide a mask sheet.

Another object of the present disclosure is to provide a mask component having the above-mentioned mask sheet.

Another object of the present disclosure is to provide a vapor-deposition method.

According to an aspect of the present disclosure, a mask sheet is provided, where the mask sheet is disposed on a mask frame. The mask sheet includes a magnetic material and has a first surface and a second surface, where the first surface of the mask sheet faces away from the mask frame, the second surface of the mask sheet faces to the mask frame, and a plurality of convex structures protrude from the first surface of the mask sheet.

According to an embodiment of the present disclosure, the convex structure has a smooth round convex shape.

According to an embodiment of the present disclosure, a height of the convex structure is 80 μm to 120 μm.

According to an embodiment of the present disclosure, the convex structure is formed using a stamping process.

According to an embodiment of the present disclosure, the mask sheet has a frame structure formed by enclosing multiple sides, and the convex structure protrudes from the first surface of each side of the mask sheet.

According to an embodiment of the present disclosure, the convex structures protruding from the first surface of each side of the mask sheet are plural.

According to an embodiment of the present disclosure, the convex structures protruding from the first surface of each side of the mask sheet are equal in number.

According to an embodiment of the present disclosure, the plurality of convex structures protruding from the first surface of each side of the mask sheet are evenly distributed along an extending direction of the side.

According to an embodiment of the present disclosure, each side of the mask sheet has a middle portion and a connecting portion at each end of the middle portion that intersects another side, and the plurality of the convex structures protruding from the first surface of each side are located in the middle portion of the side.

According to another aspect of the present disclosure, there is provided a mask component including a mask frame and a mask sheet, the mask sheet being disposed on the mask frame. The mask sheet is the mask sheet proposed by the present disclosure and described in the above embodiment.

According to yet another aspect of the present disclosure, a vapor-deposition method is provided including the following steps:

providing a mask component including a mask frame and a mask sheet disposed on the mask frame, wherein the mask sheet includes a magnetic material and has a first surface and a second surface opposite to the first surface, and the first surface of the mask sheet faces away from the mask frame and is provided with a plurality of convex structures;

sending or positioning a substrate for vapor-deposition onto the first surface of the mask sheet of the mask frame;

pressing a touch plate against the substrate such that the substrate is tightly attached between the substrate and the plurality of convex structures of the mask sheet;

applying a magnetic field to the mask sheet through the touch plate to deform the mask sheet for correcting deformation of the substrate due to gravity; and

performing vapor-deposition on the substrate.

It should be understood that the above general description and the following detailed description are only exemplary and explanatory, and do not limit the present disclosure.

This section provides an overview of various implementations or examples of the technology described in this disclosure, and is not a comprehensive disclosure of the full scope or all features of the disclosed technology.

### BRIEF DESCRIPTION OF THE DRAWINGS

By considering the following detailed description of various embodiments of the present disclosure in conjunction with the accompanying drawings, various objects, features, and advantages of the present disclosure will become more apparent. The drawings are merely exemplary illustrations of the present disclosure and are not necessarily drawn to scale. In the drawings, the same reference numerals always denote the same or similar parts.

FIG. 1 is a schematic structural diagram of a mask component according to an exemplary embodiment; and

FIG. 2 is a partial side view of the mask component shown in FIG. 1.

### DETAILED DESCRIPTION

Exemplary embodiments embodying the features and advantages of the present disclosure will be described in detail in the following description. It should be understood that the present disclosure may have various changes in different embodiments, all of which do not deviate from the scope of the present disclosure, and the descriptions and drawings therein are illustrative in nature and are not intended to limit the present disclosure.

In the following description of different exemplary embodiments of the present disclosure, reference is made to the accompanying drawings, which form a part of the present disclosure, and in which by way of example, different exemplary structures, systems, and steps that may implement various aspects of the present disclosure. It should be understood that other specific solutions of components, structures, exemplary devices, systems, and steps may be used, and structural and functional modifications may be made without departing from the scope of this disclosure. Moreover, although the terms “above”, “between”, “within”, etc. may be used in this specification to describe different exemplary features and elements of the present disclosure, these terms are used herein for convenience only, for example, according to the directions of the examples described in the drawings. Nothing in this specification should be understood as requiring a specific three-dimensional orientation of the structure to fall within the scope of this disclosure.

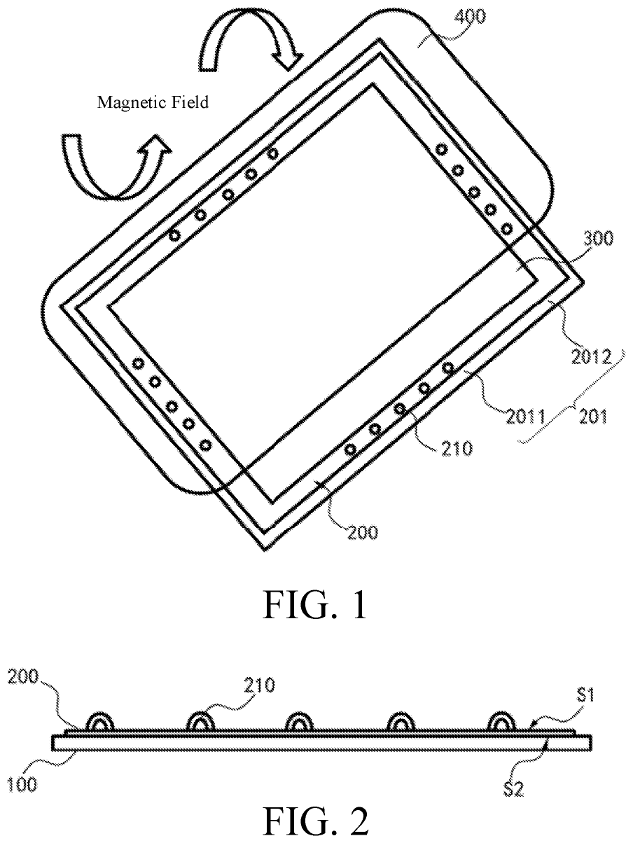

Referring to FIG. 1, a schematic structural diagram of a mask component proposed by the present disclosure is shown. That is, a schematic structural diagram of a mask sheet proposed by the present disclosure tensioned on a mask frame is shown. In this exemplary embodiment, the mask sheet proposed by the present disclosure is explained by taking a mask sheet applied to a mask frame as an example. It is understood by those skilled in the art that in order to apply the related design of the present disclosure to other types of mask components or other processes, various modifications, additions, substitutions, deletions, or other changes, which are still within the scope of the principles of the mask sheet proposed in this disclosure.

As shown in FIG. 1, in this embodiment, a mask sheet 200 proposed by the present disclosure is used for being tensioned on a mask frame 100. With reference to FIG. 2, FIG. 2 representatively shows a partial side view of a mask component capable of embodying the principles of the present disclosure, that is, showing a partial side view of the mask sheet 200 tensioned on the mask frame 100. The structural features, formation methods, and functions of the mask sheet 200 proposed by the present disclosure will be described in detail below in conjunction with the above drawings.

As shown in FIGS. 1 and 2, in this embodiment, the mask sheet 200 proposed by the present disclosure is disposed on the mask frame 100. Specifically, the mask sheet 200 includes a magnetic material (for example, a magnetic metal material such as an iron-nickel alloy or a magnetic alloy material) and has a first surface S1 and a second surface S2. The first surface S1 of the mask sheet 200 faces away from the mask frame 100, and the second surface S2 of the mask sheet 200 faces to the mask frame 100, that is, the mask sheet 200 is disposed on the mask frame 100 with the second surface S2 thereof. A plurality of convex structures 210 protrude from the first surface S1 of the mask sheet 200. A specific design of the convex structure may be flexibly selected based on the analysis of causes of producing indentation and various data simulations. Accordingly, through the above design, the mask sheet 200 proposed by the present disclosure may minimize indentation caused by the close contact between a substrate 300 and the mask sheet 200 during a vapor-deposition process, thereby improving product yield.

Further, as shown in FIG. 2, in this embodiment, the convex structure 210 may have a smooth round convex shape.

Further, as shown in FIG. 2, based on the design of the convex structure 210 in the smooth round convex shape, in this embodiment, the convex structure 210 may be a hemispherical convex shape. In other embodiments, the convex structure 210 may also select other shapes, such as a block-shaped convex shape with a rectangular or polygonal cross-section, which is not limited to this embodiment.

Further, in this embodiment, the height of the convex structure 210 may be 80 μm to 120 μm. The height may be understood as a distance between top of the convex structure 210 and the first surface S1 of the mask sheet 200, and 1 μm=1×10⁻⁶ m.

Furthermore, based on the design of the above-mentioned height of the convex structure 210, in this embodiment, the height of the convex structure 210 may be 100 μm. In other embodiments, the height of the convex structure 210 may be other designs, such as less than 80 μm or more than 120 μm, which is not limited to this embodiment.

Further, in this embodiment, the convex structure 210 of the mask sheet 200 may be formed by a stamping process, that is, the convex structure 210 is formed on the first surface S1 of the mask sheet 200 by stamping the mask sheet 200. In other embodiments, the convex structure 210 may also be configured or formed by other processes, which is not limited to this embodiment.

As shown in FIG. 1, in this embodiment, the shape of the mask sheet 200 and the mask frame 100 are substantially the same, that is, a rectangular frame structure surrounded by four sides 201. On this basis, the mask sheet 200 may be provided with the convex structure 210 on the first surface S1 of each side 201 thereof. In other embodiments, the shape of the mask sheet 200 may also be a frame structure surrounded by a plurality of sides 201, or a frame structure in another shape such as a circular ring shape, an oval ring shape, or the like. Furthermore, the mask sheet 200 may only be provided with the convex structure 210 on a part of the sides 201 thereof, which is not limited to this embodiment.

Further, as shown in FIG. 1, the design of the convex structure 210 is provided on each side 201 of the mask sheet 200. In this embodiment, each of the convex structures 210 protruding from the first surface S1 of each side 201 of the mask sheet 200 may be plural. In other embodiments, the mask sheet 200 may be provided with the plurality of convex structures 210 on part of the sides 201 thereof, while one or no convex structures 210 are provided on the other sides 201, which is not limited to this embodiment.

Further, as shown in FIG. 1, the design of the convex structure 210 is provided on each side 201 of the mask sheet 200. In this embodiment, the convex structures 210 protruding from the first surface S1 of each side 201 of the mask sheet 200 may be equal in number. In other embodiments, the convex structures 210 provided on each side 201 of the mask sheet 200 may be different in number, or may not be completely the same, which is not limited to this embodiment.

Further, as shown in FIG. 1, for any side 201 of the mask sheet 200 provided with the plurality of convex structures 210, in this embodiment, the plurality of convex structures 210 protruding from the first surface S1 of the side 201 of the mask sheet 200 may be evenly distributed along an extending direction of the side 201. In other embodiments, the plurality of convex structures 210 on the side 201 of the mask sheet 200 may also adopt other distribution methods, which may be flexibly adjusted according to actual needs, which is not limited to this embodiment.

Further, as shown in FIG. 1, based on the design of the mask frame 200 with a rectangular frame structure surrounded by four sides 201, in this embodiment, each side 201 of the mask sheet 200 has a middle portion 2011 and a connecting portion 2012 at each end of the middle portion 2011 that intersects another side 201. The convex structure 210 protruding from the first surface S1 of each side 201 may be located in the middle 2011 of the side 201, that is, each corner of the mask sheet 200 (the junction of an adjacent side 201) is not provided with the convex structure 210.

It should be noted here that the mask sheet shown in the drawings and described in this specification are just a few examples of many types of mask sheets that may adopt the principles of the present disclosure. It should be understood that the principles of the present disclosure are not limited to any details of the mask sheet or any components of the mask sheet shown in the drawings or described in this specification.

Referring to FIG. 1, a schematic structural diagram of a mask component proposed by the present disclosure is shown. In this exemplary embodiment, the mask component proposed by the present disclosure is explained by taking a vapor-deposition machine applied in an organic light emitting diode (OLED) printing process as an example. It is understood by those skilled in the art that, in order to apply the related design of the present disclosure to other types of vapor-deposition device or other semiconductor vapor-deposition processes, various modifications, additions, substitutions, deletions, or other changes are made to the following specific embodiments, and these changes are still within the scope of the principle of the mask component proposed in this disclosure.

As shown in FIGS. 1 and 2, in this embodiment, a mask component proposed by the present disclosure mainly includes a mask frame 100 and a mask sheet 200, and the mask sheet 200 is tensioned on the mask frame 100. The mask sheet 200 is the mask sheet 200 proposed by the present disclosure and described in detail in the above-described embodiment. Specifically, the mask sheet 200 has a first surface S1 and a second surface S2. The first surface S1 of the mask sheet 200 faces away from the mask frame 100, and the second surface S2 of the mask sheet 200 faces to the mask frame 100, that is, the mask sheet 200 is disposed on the mask frame 100 with second surface S2 thereof. The first surface S1 of the mask sheet 200 is provided with a plurality of convex structures 210. Accordingly, through the above design, the mask component proposed by the present disclosure may minimize the indentation caused by the close contact of a substrate 300 and the mask sheet 200 during a vapor-deposition process, thereby improving product yield.

It should be noted here that the mask component shown in the drawings and described in this specification are just a few examples of many types of mask components that may adopt the principles of the present disclosure. It should be understood that the principles of the present disclosure are by no means limited to any details or any components of the mask component shown in the drawings or described in the specification.

Based on the above exemplary description of the mask sheet and the mask component proposed by the present disclosure, an exemplary embodiment of a vapor-deposition method proposed by the present disclosure will be described below. In this exemplary embodiment, the vapor-deposition method proposed by the present disclosure is described by taking an example of vapor-depositing a substrate (such as a glass substrate) for vapor-deposition, based on a vapor-deposition machine. It is understood by those skilled in the art that in order to apply the related design of the present disclosure to other types of vapor-deposition device or to perform vapor-deposition on other types of substrates, various modifications, additions, replacement, deletions, or other changes may be made to the following specific embodiments, and these changes are still within the scope of the principle of the mask component proposed in this disclosure.

In this embodiment, the vapor-deposition method proposed in this disclosure mainly includes the following steps:

providing a mask component, including a mask frame and a mask sheet disposed on the mask frame. The mask sheet includes a magnetic material and has a first surface and a second surface opposite to the first surface. The first surface of the mask sheet faces away from the mask frame and is provided with a plurality of convex structures;

sending a substrate for vapor-deposition onto the first surface of the mask sheet of the mask frame;

pressing a touch plate against the substrate such that the substrate is tightly attached between the substrate and the plurality of convex structures of the mask sheet;

applying a magnetic field to the mask sheet through the touch plate to deform the mask sheet for correcting deformation of the substrate due to gravity; and

performing vapor-deposition on the substrate.

Through the above process method, since the mask sheet is in contact with the substrate for vapor-deposition by the plurality of convex structures, under the action of a magnetic field, a magnetic mask sheet is deformed to correct the deformation of the substrate removed by gravity, which may reduce the indentation of the substrate due to the close contact with the mask sheet.

It should be noted here that the vapor-deposition methods shown in the drawings and described in this specification are just a few examples of many vapor-deposition methods that may adopt the principles of the present disclosure. It should be understood that the principles of the present disclosure are by no means limited to any details of the vapor-deposition method or any steps of the vapor-deposition method shown in the drawings or described in this specification.

In summary, in the mask sheet proposed by the present disclosure and the mask component having the mask sheet, the mask sheet has a first surface and a second surface, the first surface of the mask sheet faces away from the mask frame, and the second surface of the mask sheet faces to the mask frame, a plurality of convex structures are protruded from the first surface of the mask sheet. Through the above design, the present disclosure may minimize the indentation caused by a close contact between a substrate and the mask sheet during a vapor-deposition process, thereby improving the product yield.

Exemplary embodiments of the mask sheet, mask component, and vapor-deposition method proposed by the present disclosure are described and/or illustrated in detail above. However, the embodiments of the present disclosure are not limited to the specific embodiments described herein. On the contrary, the components and/or steps of each embodiment may be used independently and separately from other components and or steps described herein. Each component and/or each step of one embodiment may also be used in combination with other components and/or steps of other embodiments. When introducing elements/components/etc. described and/or illustrated herein, the terms “one”, “a”, “above”, etc. are used to indicate the presence of one or more elements/components/etc. The terms “comprising”, “including,” and “having” are intended to mean an open-ended inclusion and mean that there may be additional elements/components/etc. in addition to the listed elements/components/etc. In addition, the terms “first” and “second” in the claims and the description are only used as marks, and are not intended to limit the numbers of their objects.

Although the mask sheet and the vapor-deposition method proposed by the present disclosure have been described according to different specific embodiments, those skilled in the art will recognize that the present disclosure may be changes within the spirit and scope of the claims.

1. A mask sheet, comprising:
a magnetic material, a first surface, a second surface, and at least one convex structure that protrudes from the first surface of the mask sheet.

2. The mask sheet according to claim 1, wherein the at least one convex structure has a smooth round convex shape.

3. The mask sheet according to claim 1, wherein a height of the at least one convex structure is 80 μm to 120 μm.

4. The mask sheet according to claim 1, wherein the at least one convex structure is formed using a stamping process.

5. The mask sheet according to claim 1, wherein the mask sheet has a frame structure formed by enclosing multiple sides, and the at least one convex structure protrudes from the first surface of each side of the mask sheet.

6. The mask sheet according to claim 5, wherein the at least one convex that protrudes from the first surface of each side of the mask sheet is a plurality of convex structures.

7. The mask sheet according to claim 6, wherein the plurality of convex structures protruding from the first surface of each side of the mask sheet are equal in number.

8. The mask sheet according to claim 6, wherein the plurality of convex structures protruding from the first surface of each side of the mask sheet are different in number.

9. The mask sheet according to claim 6, wherein the plurality of convex structures are not provided on the first surface of at least one side of the mask sheet.

10. The mask sheet according to claim 6, wherein the plurality of convex structures protruding from the first surface of each side of the mask sheet are evenly distributed along an extending direction of the side.

11. The mask sheet according to claim 6, wherein each side of the mask sheet has a middle portion and a connecting portion at each end of the middle portion that intersects another side, and the plurality of the convex structures protruding from the first surface of each side are located in the middle portion of the side.

12. The mask sheet according to claim 11, wherein the plurality of convex structures are not provided on the first surface in the connecting portion of each side of the mask sheet.

13. A mask component, comprising:
a mask frame and a mask sheet, the mask sheet being disposed on the mask frame, wherein the mask sheet comprises:
a magnetic material, and has a first surface and a second surface, the first surface of the mask sheet facing away from the mask frame, the second surface of the mask sheet facing towards the mask frame, and at least one convex structure protruding from the first surface of the mask sheet.

14. A vapor-deposition method, comprising:
providing a mask component that comprises a mask frame and a mask sheet disposed on the mask frame, wherein the mask sheet comprises a magnetic material and has a first surface and a second surface opposite to the first surface, and the first surface of the mask sheet faces away from the mask frame and is provided with a plurality of convex structures;
sending a substrate for vapor-deposition onto the first surface of the mask sheet of the mask frame;
pressing a touch plate against the substrate such that the substrate is tightly attached between the substrate and the plurality of convex structures of the mask sheet;
applying a magnetic field to the mask sheet through the touch plate to deform the mask sheet for correcting deformation of the substrate due to gravity; and
performing vapor-deposition on the substrate.

15. The mask component according to claim 13, wherein the mask sheet has a frame structure formed by enclosing multiple sides, and the at least one convex structure protrudes from the first surface of each side of the mask sheet.

16. The mask component according to claim 15, wherein the at least one convex structure that protrudes from the first surface of each side of the mask sheet is one of a plurality of convex structures.

17. The mask component according to claim 16, wherein the plurality of convex structures protruding from the first surface of each side of the mask sheet are equal in number.

18. The mask component according to claim 16, wherein the plurality of convex structures protruding from the first surface of each side of the mask sheet are different in number.

19. The mask component according to claim 16, wherein the plurality of convex structures are not provided on the first surface of at least one side of the mask sheet.

20. The mask component according to claim 16, wherein the plurality of convex structures protruding from the first surface of each side of the mask sheet are evenly distributed along an extending direction of the side.
